(19) United States
(12) Patent Application Publication
(10) Pub. No.: US 2015/0179947 A1
(43) Pub. Date: Jun. 25, 2015

(54) Method for Preparing a Photovoltaic Thin Film Having a Heterojunction

(71) Applicants: CENTRE NATIONAL DE LA RECHERCHE SCIENTIFIQUE (C.N. R.S), PARIS (FR); UNIVERSITE MONTPELLIER 2, SCIENCES ET TECHNIQUES, MONTPELLIER (FR)

(72) Inventors: Olivier Dautel, Teyran (FR); Lionel Derue, La Louviere (BE); Aurel Diacon, Bucarest (RO); Pietrick Hudhomme, La Meignanne (FR); Bertrand Pavageau, Villenave D'Ornon (FR); Guillaume Wantz, Pessac (FR)

(21) Appl. No.: 14/395,403

(22) PCT Filed: Apr. 19, 2013
(86) PCT No.: PCT/EP2013/058207

§ 371 Date: Mar. 9, 2015

(30) Foreign Application Priority Data
Apr. 20, 2012 (FR) 1253645
Sep. 21, 2012 (FR) 1258904

(51) Int. Cl. H01L 51/00

(52) U.S. Cl. CPC H01L 51/0047; H01L 51/424

(57) ABSTRACT

The present invention relates to a method for preparing a photovoltaic thin film having a heterojunction by depositing a composition, including a first organic electron-donor semiconductor C_{P} and a second organic electron-acceptor semiconductor C_{N}, onto a substrate and then carrying out phase segregation, including: a step (E1) of preparing a first mixture M1 including the organic semiconductors C_{N} and C_{P} within a solvent medium; and then a step (E2) of adding an additive, having at least one N3 function, to the said mixture.

### FIELD OF THE INVENTION

The present invention relates to a method for preparing a photovoltaic thin film having a heterojunction, of the type implementing a process of depositing a composition, including a first organic electron-donor semiconductor C_{P}, and a second organic electron-acceptor semiconductor C_{N}, onto a substrate and then carrying out phase segregation. The method of the invention involves a particular process of this type, which makes it possible, more specifically, to ensure thermal stabilisation of the film produced.

### STATE OF THE ART

Various methods for the preparation of photovoltaic thin film having a heterojunction (mass or volume heterojunction referred to as “bulk heterojunction” in English) are known, in particular based on mixtures of fullerene derivatives and polythiophene derivatives. It is also well known that obtaining good yields or outputs with this type of thin film is brought about by obtaining phase domains having dimensions of the order of the length of diffusion of excitons that are photogenerated in each of the materials (typically less than 40 nm).

A common recurring problem with this type of thin film is their instability over time, more specifically their thermal instability. Under the effect of heat in particular, the morphology of the layer tends to change over time, which usually leads to a general increase in the size of domains, and thus to a loss in the efficiency of the photovoltaic yields. Insofar as photovoltaic cells operate under direct light radiation which is typically sunlight, they are frequently subjected to elevated temperatures (typically 60° C. to 80° C. for a solar cell used on a roof top) and their efficiency is seen to drop over time, which constitutes one of the major barriers to the wide exploitation of organic photovoltaic cells having a heterojunction.

### SUMMARY OF THE INVENTION

An object of the present invention is to provide an effective method that makes it possible to thermally stabilise heterojunction photovoltaic thin films of the aforementioned type.

To this end, the present invention proposes to use specific cross linking agents in the synthesis medium, that is to say compounds bearing azide functions, typically intermolecular cross linking agents that carry at least two azide functions (alternatively, as explained further here below it is possible to functionalise all or part of the modified organic semiconductors with groups carrying azide functions, in which case the presence of one single azide function per modified semiconductor is sufficient in order to ensure the cross linking), and to delay the cross linking effect of the azide functions until the time of phase segregation (typically by programming this cross linking of the azide functions to occur just at the moment when the phase segregation is taking place), in particular by using the cross linking agents at a temperature that is sufficiently low at the outset.

More precisely, the object of the present invention relates to a method for preparing a photovoltaic thin film having a heterojunction by depositing onto a substrate a composition, including a first organic semiconductor hereinafter denoted as C_{P}, of the electron-donor type, and a second organic semiconductor hereinafter denoted as C_{N}, of the electron-acceptor type, and then carrying out phase segregation, the said method including the following steps:
the preparation, in one or more steps, of a mixture M comprising the semiconductors C_{P} and C_{N} and the cross linking agents bearing azide groups in a suitable solvent that is appropriate for the phase segregation, under conditions providing for the temperature to be sufficiently low so as to inhibit the precipitation by cross linking of one and/or the other of the two organic semiconductors by means of reaction of the cross linking agents; and
the depositing, on all or part of the surface of a substrate, of the mixture M thus produced and subsequently, carrying out the phase segregation by raising the temperature during or after this phase segregation and/or subjecting the reaction medium to a UV radiation having a suitable wavelength in a manner so as to be placed under conditions in which the cross linking additive reacts in order to form covalent bonds with at least a portion of the organic semiconductors, due to which a cross linking within the photovoltaic thin film produced is obtained.

According to a first embodiment, the process involves making use according to the invention of intermolecular cross linking agents other than the semiconductors C_{P} and C_{N}. In this case, the method of the invention typically includes the following steps:
(E1) the preparation of a first mixture M1 comprising the organic semiconductors C_{N} and C_{P} in a solvent medium; then
(E2) the addition to this mixture M1 of a cross linking additive bearing at least two azide functions and possibly a solvent, under conditions providing for the temperature to be sufficiently low so as to inhibit the precipitation by cross linking of one and/or the other of the two organic semiconductors with the cross linking additive during the step (E2), in a manner so as to form a mixture M comprising the semiconductors C_{P} and C_{N} and the additive in a suitable solvent that is appropriate for the phase segregation (in the step (E2), the temperature is raised and/or the reaction medium is subjected to a UV radiation having a suitable wavelength during or after the phase segregation, and typically only after the phase segregation); and then
(E3) the depositing, on all or part of the surface of a substrate, of the mixture M thus produced and subsequently, carrying out the phase segregation, by raising the temperature during or after this phase segregation and/or subjecting the reaction medium to a UV radiation having a suitable wavelength in a manner so as to be placed under conditions in which the cross linking additive reacts in order to form covalent bonds with at least a portion of the organic semiconductors, due to which a cross linking within the photovoltaic thin film produced is obtained.

According to a second embodiment, the azide functions that induce the cross linking are carried by all or part of the semiconductors C_{P} and C_{N}, the azide functions preferably being carried by the semiconductor C_{N} with the acceptor character thereof not being modified by the azide functions. According to this embodiment, it is generally not necessary to use intermolecular cross linking agents of such type as those used in the first embodiment, although making use in the implementation of such agents is however not excluded in the second mode according to certain particular variant embodiments. In its second embodiment, the method of the invention typically includes the following steps:
(E1) the preparation of a first mixture M1 comprising only a portion of the organic semiconductors C_{N} and C_{P} in a solvent medium; then
(E2) the addition to this mixture M of the remainder of the organic semiconductors, previously modified by the grafting of azide functions and possibly a solvent, under conditions providing for the temperature to be sufficiently low so as to inhibit the precipitation by cross linking of one and/or the other of the two organic semiconductors with the cross linking additive during the step (E2), in a manner so as to form a mixture M comprising the semiconductors C_{P} and C_{N} a portion of which is a modified by the azide functions in a suitable solvent that is appropriate for the phase segregation; and then
(E3) the depositing, on all or part of the surface of a substrate, of the mixture M thus produced and subsequently, carrying out the phase segregation; and, during or after this phase segregation, and typically only after the phase segregation, raising the temperature and/or subjecting the reaction medium to a UV radiation having a suitable wavelength in a manner so as to be placed under conditions in which the cross linking additive reacts in order to form covalent bonds with at least a portion of the organic semiconductors, due to which a cross linking within the photovoltaic thin film produced is obtained.

In this second embodiment, the steps (E1) and (E2) are generally distinct, but the process may alternatively include the steps (E1) and (E2) merged into one common single step of preparation of the mixture M by mixing all of the semiconductors (functionalised and non-functionalised) in a suitable solvent.

According to the aforementioned second embodiment, whether or not the steps (E1) and (E2) are merged, the organic semiconductors, previously modified by the grafting of azide functions perform the role of cross linking agents in the step (E3). These organic semiconductors previously modified by the grafting of azide functions are preferably organic semiconductors C_{N} functionalised by at least one group bearing at least one azide function. Typically, the mixture M1 used in implementation in the step (E1) comprises only a portion of the organic semiconductors C_{N} and all of the organic semiconductors C_{P} and during the step (E2) the rest of the organic semiconductors C_{N}, previously functionalised with at least one group bearing at least one azide function are added in order to form the mixture M.

According to this embodiment, the functionalisation of the organic semiconductors by at least one azide group may be performed by any means known as such. In particular, it may be carried out based on semiconductors that carry ester functions —COOAlk wherein Alk represents an alkyl group, like for example PCBM (Methyl[6,6]-phenyl-C₆₁-butyrate, described in greater detail below) by means of hydrolysis of the ester function followed by esterification of the acid function obtained upon conclusion of the hydrolysis with a compound having the formula HO-A-N₃, where A is a hydrocarbon chain, typically an alkylene group having the formula —(CH₂)ₘ— where m typically ranges from 2 to 6, due to which is formed a group of the type —COO-A-N₃, typically a group —COO—(CH₂)ₘ—N₃ on the organic semiconductors.

By way of an example, it may be possible to use as semiconductors bearing azide groups the compounds referred to as [60]PCB-C3-N3 or [60]PCB-C6-N3 obtained by hydrolysis of PCBM into the corresponding acid PCBA (abbreviation for “[6,6]-phenyl-C₆₁-butyric acid”), in particular in accordance with the procedure described in J. Org. Chem. 60, pp. 532-538 (1995), and followed by esterification of the PCBA obtained respectively with HO—(CH₂)₃—N₃ or with HO—(CH₂)₆—N₃, typically in accordance with the routes described here below:

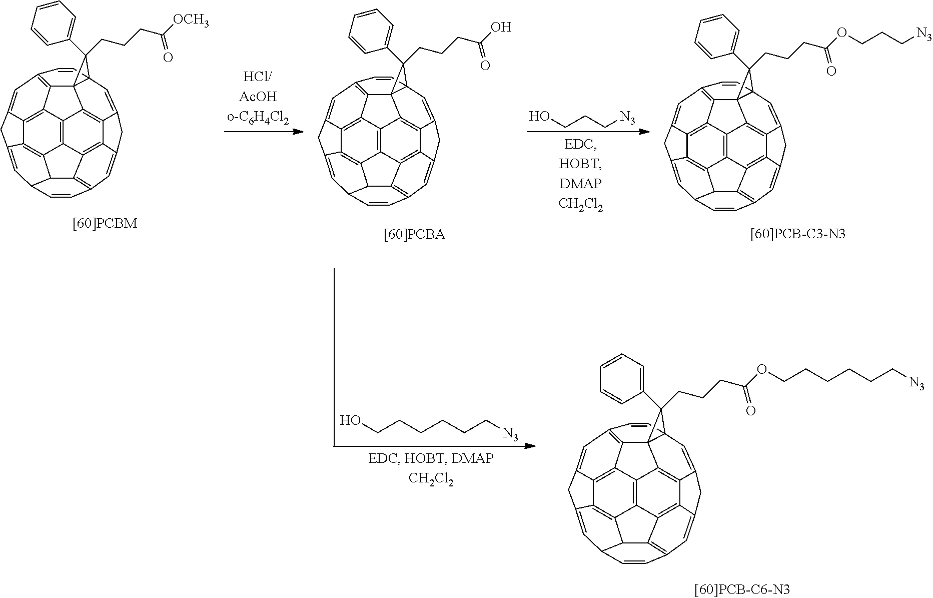

The term “azide” within the scope of the present invention is used to refer to a group having the formula —N═N⁺=N⁻ (more simply denoted as —N₃, for the purposes of brevity).

Within the context of the present invention, the inventors have now empirically demonstrated that the cross linking additive used in the steps (E2) and (E3) makes it possible to ensure thermal stabilisation of the photovoltaic properties of the thin layer. In particular, it appears that the use in implementation of the additive under the conditions provided for the steps (E2) and (E3) provide the ability to reduce, or even to inhibit, the formation of crystals (typically, microcrystals of PCBM) that are observed otherwise when the photovoltaic film is subjected to high temperatures, typically above 100° C., for example around 150° C. The cross linking additive employed according to the invention more generally provides the ability to prevent the degradation of the photovoltaic properties of the thin film when it is subjected to the kind of high temperatures as mentioned above. In some cases, the additive on the contrary, even allows for an improvement in the photovoltaic properties when it is subjected to a heat treatment, as has been illustrated in the examples given at the end of this description. Without intending to be bound to a particular theory, it appears to be possible to argue that this stabilisation can be explained by the fact that the cross linking agent solidifies, to some extent, the structure obtained by phase segregation.

The method of the invention results in particular in the stabilisation of the photovoltaic efficiency of the coating, which is reflected in particular by an increase in the power conversion output (also referred to as PCE, abbreviated from “Power Conversion Efficiency”) as well as in the filling factor (FF, commonly known as “Fill Factor” in English) of the photovoltaic devices that implement a photovoltaic coating such as is obtained according to the invention. The values of PCE and FF are variable quantities that are characteristic of photovoltaic devices that are commonly used and which are defined in particular in the article “Conjugated Polymer-Based Organic Solar Cells” published in Chemical Reviews, 107, (4), pp. 1324-1338 (2007). For the record, they are measured by implementing the photovoltaic device comprising the material to be tested as a photovoltaic diode. The value of the PCE corresponds to the ratio of the maximum power ouput by the material in relation to the power of the luminous flux illuminating it. As for the fill factor (between 0 and 1) it reflects the extent to which the nature of the material is far from or close to that of an ideal diode (a fill factor of 1 corresponds to the case of an ideal diode).

The method provided in this present invention may be used with a large number of organic semiconductors.

Thus, one may in particular use by way of an organic semiconductor compound C_{N} any electron acceptor material known to exhibit such properties, which may for example be selected from among the following compounds:
fullerenes and fullerene derivatives, such as C60, C70, PCBM (also known as “PC₆₀BM” or, more precisely, PC61BM, having the formula Methyl[6,6]-phenyl-C₆₁-butyrate), and PC₇₁BM (having the formula Methyl[6,6]-phenyl-C₇₁ butyrate, which is sometimes referred to, rather improperly, as “PC₇₀BM”);
types of polymers such as Polyfluorene;
PCNEPV (Poly[oxa-1,4-phenylene-(1-cyano-1,2-vinylene)-(2-methoxy-5-(3,7-dimethyloctyloxy)-1,4-phenylene)-1,2-(2-cyanovinylene)-1,4-phenylene]); and
poly(styrene sulfonate) (PSS).

The fullerene derivatives, in particular PC₆₁BM (Methyl[6,6]-phenyl-C₆₁-butyrate), or PC₇₁BM (Methyl[6,6]-phenyl-C₇₁ butyrate) mentioned above, prove to be most particularly well suited as the organic semiconductor compound C_{N} according to the present invention. These derivatives are particularly well cross linked within the context of the method of the invention, which prevents the subsequent recrystallisation thereof, which thereby results in enhanced thermal stability as compared to photovoltaic coatings based on unstabilised fullerenes according to the present invention.

By way of an organic semiconductor compound C_{P}, any material known to exhibit a P type semiconductor character may be employed in the context of the present invention. Advantageously, the organic semiconductor compound C_{P} is a conjugated organic polymer preferably selected from among the following compounds:
polythiophene derivatives, such as P3HT (Poly[3-hexylthiophene-2,5-diyl]);
tetracene,
anthracene,
derivatives of PPV (Polyphenylene vinylene) such as MDMO-PPV (poly[2-methoxy-5-(3′,7′-dimethyloctyloxy)-p-phenylene vinylene]) and MEH-PPV (poly[2-methoxy-5-(2′-ethyl hexyloxy)-1,4-phenylene vinylene]); and
polymers referred to as “low band gap polymers”, also known as third generation semiconducting polymers, including in particular the derivatives referred to as derivatives with a “push-pull structure”, like PCDTBT (Poly[N-9′-hepta-decanyl-2,7-carbazole-alt-5,5-(4′,7′-di-2-thienyl-2′,1′,3′-benzothiadiazole)]).

The polythiophene derivatives such as P3HT (Poly[3-hexylthiophene-2,5-diyl]), P3BT (Poly[3-butylthiophene-2,5-diyl]), P3OT (Poly[3-octylthiophene-2,5-diyl]) or P3DT (Poly[3-decylthiophene-2,5-diyl]) are particularly suitable as the organic semiconductor compound C_{P} in the method of the present invention.

The organic semiconductor compounds (C_{N} and C_{P}) that are used in the context of the present invention may also be selected from conjugated aromatic molecules containing at least three aromatic rings, possibly fused. The organic semiconductor compounds of this type may include, for example 5, 6 or 7 conjugated aromatic rings, preferably 5 or 6. These compounds may well be monomers, or oligomers, or polymers.

The aromatic rings present on the organic semiconductors of the aforementioned type may include one or more heteroatoms selected from among Se, Te, P, Si, B, As, N, O or S, preferably from N, O or S. Moreover they may also be bound by conjugate binding groups, such as the groups —C(T1)=C(T2)-, —C≡C—, —N(Rc)—, —N═N—, —N═C(R′)—, where T1 and T2 are, for example, independently, H, Cl, F, or a C1 to C6 alkyl group (that is to say, having 1 to 6 carbon atoms), preferably a C4 group and Rc represents H, an alkyl possibly substituted or an aryl possibly substituted.

These aromatic rings may in addition be possibly substituted by one or more group(s) selected from among the alkyl-, alkoxy polyalkoxy thioalkyl acyl-, aryl- or substituted aryl-, halogen-(especially with F or Cl, preferably F), cyano-, nitro groups, and the secondary or tertiary amines possibly substituted (preferably amines having the formula —NRaRb in which each one of Ra and Rb, is independently H, or an alkyl group possibly substituted (and possibly fluorinated, or even perfluorinated), an aryl group possibly substituted (for example fluorinated), an alkoxy or polyalkoxy group.

More generally, the organic semiconductor compounds (C_{N} and C_{P}) which may be used in implementation according to the present invention include compounds and polymers selected from among the conjugated hydrocarbon polymers and oligomers such as polyacenes, polyphenylenes, poly(phenylene vinylenes), polyfluorenes, condensed aromatic hydrocarbons such as tetracene, chrysene, pentacene, pyrene, coronene, and more preferably the soluble derivatives of these compounds, such as substituted p-phenylene, like for example p-quaterphenyl (p-4P), p-quinquephenyl (p-5P), p-sexiphenyl (p-6P), or the substituted derivatives thereof such as poly(3-substituted thiophene), 3,4-disubstituted poly(thiophenes), polybenzothiophenes, polyisothianaphthenes, poly(λ-substituted pyrrole), poly(3-substituted pyrrole), poly(3,4-bisubstituted pyrrole), polyfurans, polypyridines, poly-1,3,4-oxadiazoles, polyisothianaphthenes, poly(l-substituted aniline), poly(2-substituted aniline), poly(3-substituted aniline), poly(2,3-bisubstituted aniline), polyazulenes, polypyrenes, compounds of pyrazoline polyselenophenes, polybenzofurans, polyindoles, polypyridazines, benzidine compounds, stilbene compounds, triazines, porphines, phthalocyanines, fluorophtalocyanines, naphthalocyanines or fluoronaphtalocyanines, possibly metallated, fullerenes and the derivatives thereof, diphenoquinones, 1,3,4-oxadiazoles, 11,11,12,12-tetracyanonaptho-2,6-quinodimethane, [alpha], [alpha]′-bis(dithieno[3,2-b2′,3′-d]thiophene), substituted anthradithiophenes and 2,2′-bibenzo[1,2-b: 4,5-b′]dithiophene.

The invention is in particular well suited to the specific case of the following pair of organic semiconductor compounds:

C_{N}=PCBM (Methyl[6,6]-phenyl-C₆₁-butyrate); and

C_{P}=P3HT (poly(3-hexylthiophene)),

which corresponds to a pair of typical polymers in the context of the preparation of organic photovoltaic compositions, described for example in Advanced Materials, vol. 23, pp. 3597-3602 (2011).

The invention is also well suited to the following particular pair of organic semiconductor compounds:

C_{N}=PCBM (Methyl[6,6]-phenyl-C₇₁-butyrate); and

C_{P}=P3HT (poly(3-hexylthiophene)).

For these particular C_{N}/C_{P} pairs (and more generally for all the pairs of the type fullerene derivative/polythiophene derivative), the use in implementation of the cross linking agent according to the invention provides the ability in general to carry out the cross linking of the compound of type C_{N} (PCBM or similar) during the step (E3), which makes it possible to achieve a particularly effective stabilisation of the photovoltaic properties of the thin film produced (this cross linking inhibits in particular the natural tendency that fullerenes and their derivatives have to crystallise).

In particular, when employing semiconductor compounds C_{N} of the fullerene derivative type, it is advantageous for the molar ratio of the cross linking agent/semiconductor C_{N} to be less than 2, more preferably less than 1, in particular less than 0.5, for example less than or equal to 0.25. The inventors have empirically demonstrated that with a low ratio within these ranges, the effect of thermal stabilisation is most particularly pronounced and inhibits the phenomena of recrystallization of fullerenes that take place in the absence of a cross linker. Furthermore, the inventors have empirically demonstrated that the introduction of the cross linking agent does not affect the photovoltaic performance of the thin film, and this is most particularly so with a ratio within the abovementioned ranges.

Depending on the nature of the semiconductor compounds C_{N} and C_{P} used in implementation in the method of the invention, the exact nature of the solvent medium used in the step (E1) is to be adapted in order to obtain the desired phase segregation. The principles of phase segregation and the rules governing the selection of suitable solvents have been described in particular in Advanced Functional Materials, vol. 18, pp. 1783-1789 (2008).

By way of an example, when use is made of a fullerene derivative of the PCBM type as a semiconductor C_{N} and of a polythiophene derivative such as P3HT as a semiconductor C_{P}, it is for example possible to use in the step (E1) one or more solvents selected from among chlorobenzene, dichlorobenzene (o-dichlorobenzene, m-dichlorobenzene, p-dichlorobenzene), trichlorobenzene, benzene, toluene, chloroform, dichloromethane, dichloroethane, xylenes (in particular ortho-xylene), α,α,α-trichlorotoluene, methylnaphthalene (1-methylnaphthalene and/or 2-methylnaphthalene), chloronaphthalene (1-chloronaphthalene and/or 2-chloronaphthalene). The cross linking agent may be introduced in the step (E2) in the form of a solution in one of these solvents which is prepared prior to the introduction into the mixture M1.

According to one interesting embodiment, the solvent used in the step (E1) (and, as appropriate in the step (E2)) comprises at least one or more xylene(s), for example, ortho-xylene.

In the most general case, the concentration of the semiconductor C_{N} in the mixture M1 of the step (E1) and in the medium obtained at the completion of the step (E2) is preferably comprised between 5 and 50 mg/mL, more preferably between 10 and 30 mg/mL, for example between 15 and 25 mg/mL. The concentration of the semiconductor C_{P} in the mixture M1 of the step (E1) and in the medium obtained at the completion of the step (E2) is in similar fashion, preferably comprised between 5 and 50 mg/mL, more preferably between 10 and 30 mg/mL, for example between 15 and 25 mg/mL.

The cross linking agent is typically introduced in the step (E2) in the form of a solution, in a solvent that may or may not be identical to that in the mixture M1 prepared in the step (E1). The term “solvent” as used in the present description with reference to the steps (E1) and (E2) refers to a single solvent or indeed, more often, to a mixture of multiple solvents (also known as “solvent system”).

In the step (E3), the phase segregation can be achieved according to any means known per se, for example by means of a heat treatment (for example by annealing) and/or drying process, in particular under solvent vapour (which allows for slowing the kinetics of the drying so as to allow the mixture to relax), for example according to the so called “solvent annealing” method.

According to a particular embodiment, the steps (E1), (E2) and (E3) are carried out under the following conditions:
(E1) the first mixture M1 is prepared and comprises, in the solvent medium S1, the organic semiconductor C_{P} and the second organic semiconductor C_{N};
(E2) to this mixture M1, the cross linking additive is added in the form of a mixture M2 comprising of the additive in a second solvent medium S2, due to which a mixture M is obtained that comprises of a solvent S including the solvent S1 and the optional solvent S2,
   wherein the solvent S of the mixture M is constituted of a mixture of:
      a first fraction F1 consisting of a solvent or mixture of solvents having a boiling point lower than that of the compounds C_{P} and C_{N} and which is capable of solvating the two compounds C_{P} or C_{N};
      a second fraction F2, miscible with the first fraction, consisting of a solvent or mixture of solvents which has a boiling point that is higher than that of the fraction F1 and lower than that of the compounds C_{P} and C_{N} and which is capable of selectively solvating one of the compounds C_{P} or C_{N} but not the other (that is to say, unable to solvate respectively C_{N} or C_{P});
   this addition being carried out under conditions providing for the temperature to be sufficiently low so as to inhibit the cross linking of one and/or the other of the two organic semiconductor by the cross linking agent during the step (E2);
(E3) the mixture M thus produced is deposited on all or part of the surface of a substrate, and the solvent S present in the deposit thus produced is eliminated by means of evaporation, and simultaneously or subsequently, the medium is brought to a temperature that is sufficient in order to ensure that the cross linking is performed.

In light of the specificities of the fractions F1 and F2 used, during the step (E3) of drying of the solvent S, a very particular process happens to takes place, which induces the formation of a specific morphology in the coating obtained ultimately.

More specifically, during the step (E3), the fraction F1, which is more volatile than the fraction F2, evaporates in the first place, which leads to an enrichment in the F2 phase in the solvent medium of the deposit obtained, which makes the solvent medium increasingly less able to solvate the compound that the fraction F2 is not able to solvate. Subsequently there follows the desolvation of at least a portion of one of the compounds C_{P} or C_{N} capable of leading to a phenomenon of demixing of this compound, the other compound (respectively C_{N} or C_{P}) remaining on the contrary, in the initial stage, in a solvated form, taking into account the presence of a sufficient amount of fraction S1 in the medium, which is not yet evaporated. It is only in a second phase of the step (E3) that the entirety of the solvents is found to be evaporated, so as to leave as a coating a mixture of the compounds C_{N} and C_{P} substantially free of solvent. In the light of this desolvation in two stages of the compounds C_{N} and C_{P} and the immiscible nature of the compounds C_{N} and C_{P}, the solid coating obtained on the substrate has a specific morphology at the nanoscale, with a high contact interface between the compounds C_{N} and C_{P}

For more details on this subject, reference may be made to the patent application WO2011/036421.

Whatever be the exact mode of carrying out the steps (E1), (E2) and (E3), they are specifically conducted under relevant conditions such that the cross linking by the cross linking agent is inhibited in the step (E2), so as to be brought about only in the step (E3). This specificity of the method provides the ability to obtain a particularly interesting cross linking, which schematically, solidifies the structure that forms by means of phase segregation in the step (E3). To this end, the step (E2) is conducted at a temperature below the temperature that results in the cross linking (typically at a temperature lower than 50° C., more preferably lower than 40° C., or even lower than 30° C.). Typically, the temperature is subsequently increased, only after the step (E2), beyond the temperature at which the cross linking takes place. Alternatively, the step (E3) may be carried out by exposing the mixture to a UV radiation, typically to a radiation at 254 nm, with or without (preferably without) increase in temperature. It is to be noted that the step (E1) generally requires a hot dissolution (at a temperature above 60° C. in general) in order to form the mixture M1. Following this hot mixing, it is essential to cool the medium prior to implementing the process for the mixture formed in the step (E2).

In this context, it is to be noted that the step (E2) provides the advantage of being able to be conducted at ambient temperature, which presents a highly significant economic interest when the method is used on an industrial scale.

According to a particular embodiment of the invention, the cross linking agent is 4,4′-bis(azidomethyl)-1,1′-biphenyl having the formula N₃—CH₂-Ph-Ph-CH₂—N₃, where Ph is a phenyl group, hereinafter designated by BPN. This compound can in particular be synthesised in accordance with the method described in Journal of the American Chemical Society, 127 (36), pp. 12434-12435 (2005).

In the case of the use of BPN:
the BPN concentration in the mixture formed in the step (E2) is typically less than 0.1 mg/mL and/or with a molar ratio of BPN/C_{N} that is less than 2;
the semiconductor compound C_{N} is preferably a fullerene derivative, for example PCBM, with a BPN/C_{N} ratio of preferably less than 2, more preferably less than 1, in particular less than 0.5, for example less than or equal to 0.25;
the temperature in the step (E2) is preferably lower than 30° C., for example between 15° C. and 25° C. (ambient temperature, for example).

More generally, it may be possible to use according to the invention other compounds bearing exactly two azide groups, like for example the compounds selected from the following list:

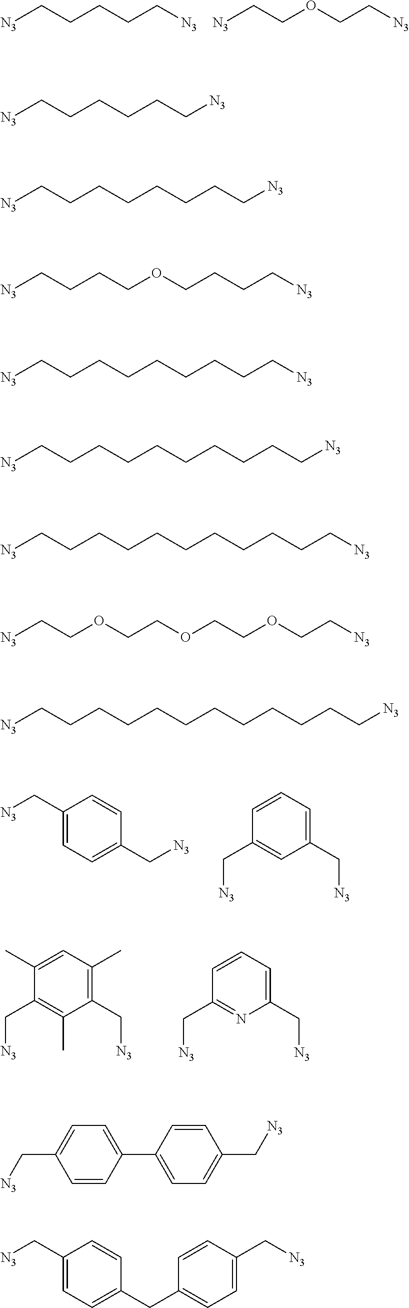

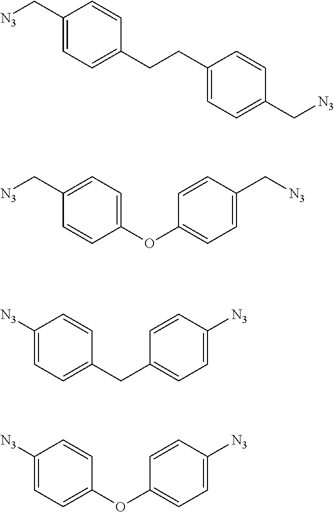 [SMILES: [N-]=[N+]=NCc1ccc(CCc2ccc(CN=[N+]=[N-])cc2)cc1 ; [N-]=[N+]=NCc1ccc(Oc2ccc(CN=[N+]=[N-])cc2)cc1 ; [N-]=[N+]=Nc1ccc(Cc2ccc(N=[N+]=[N-])cc2)cc1 ; [N-]=[N+]=Nc1ccc(Oc2ccc(N=[N+]=[N-])cc2)cc1]

Alternatively, it may be possible to use according to the invention compounds bearing more than two azide groups, for example bearing exactly three or four azide groups, or even more, for example:

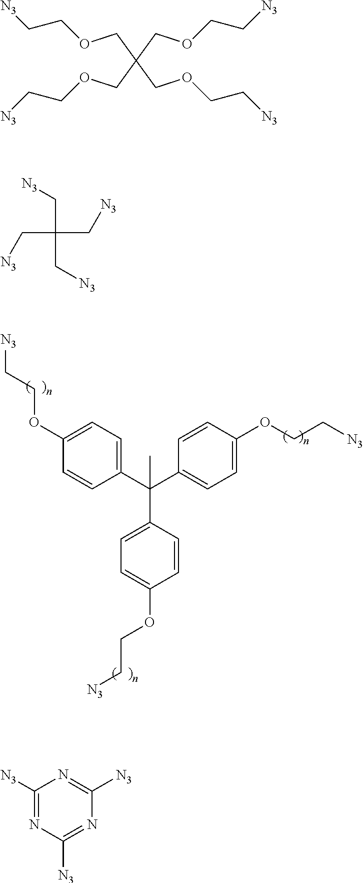

According to another embodiment of the invention, the cross linking agent used in the step (E2) is an agent which performs in addition the role of a texturising agent during the formation of the film in the step (E3). According to this embodiment, the cross linking agent is a compound which, in addition to bearing azide groups, exhibits the character of a selective solvent of one of the compounds C_{P} or C_{N} and not of the other.

More specifically, according to this particular embodiment, the method is conducted under the following conditions:
(E1) the first mixture M1 is prepared and comprises, in a solvent S1, the organic semiconductor C_{P} and the second organic semiconductor C_{N};
(E2) to this mixture M1, is added a composition including at least one cross linking additive of the aforementioned type, possibly dissolved in the same solvent S1 as that of the mixture M1;
   wherein:
      the solvent S1 is a solvent medium having a boiling point lower than that of the compounds C_{P} and C_{N} and which is capable of solvating the two compounds C_{P} or C_{N} and
      the cross linking additive is a compound miscible with the solvent S1, which has a boiling point that is higher than that of S1 and lower than that of the compounds C_{P} and C_{N} and which is capable of selectively solvating one of the compounds C_{P} or C_{N} but not the other (that is to say, unable to solvate respectively C_{N} or C_{P});
   this addition being carried out under conditions providing for the temperature to be sufficiently low so as to inhibit the cross linking of one and/or the other of the two organic semiconductors by the cross linking agent during the step (E2),
(E3) the mixture M thus produced is deposited on all or part of the surface of a substrate, and the solvent S1 is eliminated by means of evaporation, due to which a texturing of the film is obtained, and subsequently, the textured coating thus obtained is brought to a temperature that is sufficient in order to ensure that the cross linking is performed.

By way of examples of cross linking agents that may be used according to this specific embodiment, in particular mention may be made of the following:
1,10-diazidodecane having the formula

N₃—(CH₂)₁₀—N₃
which can for example be synthesised by the method described in Journal of the American Chemical Society, vol 127, pp. 12434-12435 (2005),
compounds having the formula N₃—Ra—O—C═O—Rb—C═O—O—Ra—N₃,

where:
—Ra— is a saturated or unsaturated, linear or branched hydrocarbon chain, preferably linear, with Ra being preferably an -alkyl-group or -alkenyl-group, advantageously comprising of 2 to 18 carbon atoms; and
—Rb— is a saturated or unsaturated, linear or branched hydrocarbon chain, preferably linear, with Ra being preferably an -alkyl-group or -alkenyl-group, advantageously comprising of 1 to 18 carbon atoms,

such as, for example, bis(8-azidooctyl) 2-methylpentanedioate having the formula:

N₃—(CH₂)₈—O—C═OCHCH₃CH₂CH₂C═O—O(CH₂)₈N₃

The compounds having the formula N₃—Ra—O—C═O—Rb—C═O—O—Ra—N₃ may typically be prepared by means of reacting a diacid having the formula HOOC—Rb—COOH where Rb is as defined here above (2-methyl-glutaric acid, for example) with a compound having the formula HO—Ra—N₃ where Ra is as defined here above, preferably in the presence of para toluene sulfonic acid as shown in the Example 3 provided here below.

These compounds that are useful in the context of the implementation of the step (E2) are compounds which, to the inventors' knowledge, have never previously been described. They constitute, according to another aspect, a specific object of the present invention.

These cross linking agents “having a texturising effect” may be used in particular for the production of a coating based on a mixture of PCBM/P3HT type semiconductors, where they may be used with a solvent S1 of the prescribed type in order to carry out the depositing of this mixture of polymers of this type, known per se. In particular, the solvent S1 used according to this embodiment may comprise of one or more solvents selected from among chlorobenzene, dichlorobenzene (o-dichlorobenzene, m-dichlorobenzene, p-dichlorobenzene), trichlorobenzene, benzene, toluene, chloroform, dichloromethane, dichloroethane, xylenes (in particular ortho-xylene), α,α,α-trichlorotoluene, methylnaphthalene (1-methylnaphthalene and/or 2-methylnaphthalene), chloronaphthalene (1-chloronaphtalene and/or 2-chloronaphthalene). According to one embodiment, the solvent S1 comprises at least one xylene, preferably at least ortho-xylene. Preferably, the fraction S1 is constituted entirely of one or more xylene(s), for example ortho-xylene.

According to another more specific aspect, the object of the present invention relates to substrates provided with a coating of a photovoltaic nature of the type obtained (that is to say, obtained or capable of being obtained) in accordance with the method detailed above in the present description.

In particular, the object of the invention relates to the use of the method of the invention for the production of photovoltaic cells. In this context, the photovoltaic coating is generally deposited on an anode (generally an anode transparent to radiations in the visible range, for example of ITO, advantageously a film of ITO deposited on a sheet of plastic material). The anode may be coated beforehand with a layer of a conductive material. Subsequently, a photovoltaic thin film according to the invention is deposited (by carrying out the steps (E1), (E2) and (E3)), and then a cathode is deposited on the photovoltaic coating (for example in the form a metal over layer, such an over layer of aluminium). The method of the invention may indeed also be implemented in order to fabricate devices that make use of the extraction of holes or the extraction of electrons by the upper and lower electrodes (direct or inverted devices).

Various aspects and preferred characteristic features of the invention are illustrated in the examples of implementation provided here below, wherein photovoltaic coatings according to the invention have been produced, based on:

(i) a P type organic semiconductor (electron donor):
P3HT available from Plextronics or Sigma-Aldrich

(ii) an N type organic semiconductor (electron acceptor):
PCBM (Methyl[6,6]-phenyl-C₆₁-butyrate) marketed by Solaris Chem. Inc.

(iii) a cross linking agent which is, according to the example:
BPN, synthesised in accordance with the method described in Journal of the American Chemical Society, 127(36), pp. 12434-12435 (2005),
1,10-diazidodecane having the formula N₃—(CH₂)₁₀—N₃, synthesised in accordance with the method described in Journal of the American Chemical Society, vol 127, pp. 12434-12435 (2005), or

Bis(8-azidooctyl) 2 methylpentanedioate having the formula

N₃—(CH₂)₈—O—C═OCHCH₃CH₂CH₂C═O—O(CH₂)₈N₃

### EXAMPLES

### Example 1

### Production of a Cross Linked Photovoltaic Coating (BPN)

Preparation of a First Solution S Containing the Semiconductors N and P

20 mg of P3HT and 20 mg of PCBM were dissolved in 1 mL of ODCB (ortho dichlorobenzene), by bringing the mixture to 60° C. under agitation (hot plate), in a manner so as to obtain a stock solution S.

The solution S thus obtained was allowed to cool down to ambient temperature (20° C.).

### Preparation of a Second Solution S′ Containing the Cross Linking Agent

A solution S′ consisting of BPN in ODCB was prepared at a concentration of 20 mg/mL of BPN.

### Mixing of the Two Solutions

Once the first solution S had cooled to 20° C., 50 μL of the solution S′ also at a temperature of 20° C., was introduced therein, whereby a composition was obtained that hereinafter is referred to as photovoltaic “ink 1”.

Immediate Production of the Photovoltaic Coating from the Mixture

Once the mixture had been prepared, the ink 1 was deposited in the form of a thin film on a glass plate. The film deposition was carried out by spin coating at 2000 revolutions per minute, with 5 seconds of acceleration and 60 seconds at 2000 revolutions per minute. In this example, as in the following ones, useful results are also obtained with speeds of only 1000 revolutions per minute and 1 second of acceleration.

The deposition was carried out by making use of a freshly prepared mixture. In this regard, it is to be noted that the film deposition should be carried out within a period of minutes following the mixing of the solutions S and S′.

Subsequently the annealing at 80° C. was then carried out in order to ensure the cross linking.

### Example 2

### Production of a Cross Linked Photovoltaic Coating (N₃—(CH₂)₁₀—N₃)

### Preparation of a First Solution S Containing the Semiconductors N and P

20 mg of P3HT and 20 mg of PCBM were dissolved in 1 mL of ODCB, by bringing the mixture to 60° C. under agitation (hot plate), in a manner so as to obtain a stock solution S.

The resulting solution S thus obtained was allowed to cool down to ambient temperature (20° C.).

### Preparation of a Second Solution S′ Containing the Cross Linking Agent

A solution S′ consisting of N₃—(CH₂)₁₀—N₃ in ODCB was prepared at a concentration of 20 mg/mL of N₃—(CH₂)₁₀—N₃.

### Mixing of the Two Solutions

Once the first solution S had cooled to 20° C., 25 μL of the solution S′ also at a temperature of 20° C., was introduced therein, whereby a composition was obtained that hereinafter is referred to as “ink 2”.

Immediate Production of the Photovoltaic Coating from the Mixture

Once this mixture had been prepared, the ink 2 was deposited in the form of a thin film on a glass plate. The film deposition was carried out by spin coating at 2000 revolutions per minute, with 5 seconds of acceleration and 60 seconds at 2000 revolutions per minute.

The deposition was carried out by making use of a freshly prepared mixture. In this regard, it is to be noted that the film deposition should be carried out within a period of minutes following the mixing of the solutions S and S′.

Subsequently the annealing at 80° C. was then carried out in order to ensure the cross linking.

### Example 3

### Production of a Cross Linked Photovoltaic Coating (bis(8-azidooctyl) 2-méthylpentanedioate)

### Preparation of (bis(8-azidooctyl) 2-methylpentanedioate)

The synthesis of bis(8-azidooctyl) 2-methylpentanedioate was carried out in one step from 8-azido-1-octanol (N₃(CH₂)₈OH) according to the Schematic Diagram 1 here below. The 8-azido-1-octanol (N₃(CH₂)₈OH) was synthesised from the commercially available product 8 chloro-1-octanol (Cl(CH₂)₈OH) in accordance with an operating procedure described by Pukin, Aliaksei V.; Van Lagen, Barend; Visser, Gerben M.; Wennekes, Tom; Zuilhof, Han; Florack, Dion E A; Brochu, Denis; Gilbert Michel in Organic and Biomolecular Chemistry, vol. 9, 5809-5815 (2011).

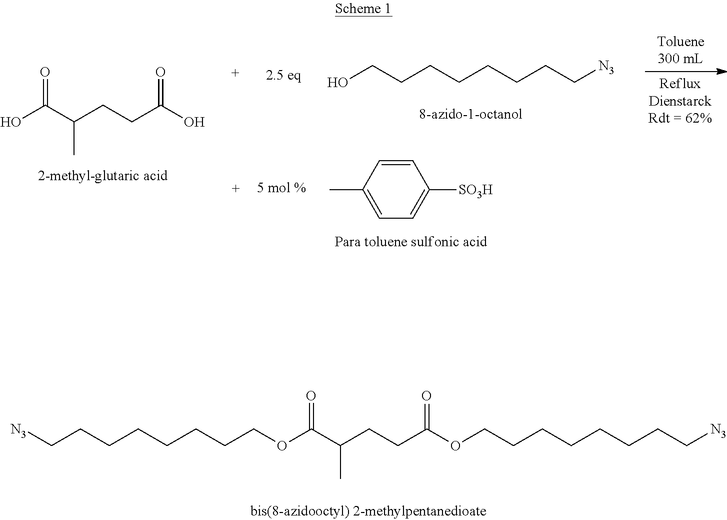

In a 500 mL flask, 5 mol % of para toluene sulphonic acid (150 mg, 0.78 mmol) was added to a solution of 2-methyl-glutaric acid (2.3 g, 16 mmol) and 2.5 equivalents of 8-azido-1-octanol (6.9 g, 40 mmol) in 300 mL of anhydrous toluene. A Dean-Stark apparatus was mounted on top of the reaction assembly and it was refluxed for a period of 48 hours. The water (0.57 mL) generated during the formation of the diester was removed by means of the Dean Stark apparatus. After returning to ambient temperature, the mixture was washed twice with an aqueous sodium hydroxide solution (4 g of NaOH in 250 ml water) and then washed twice with water (2×250 mL). The organic phase was dried over Na₂SO₄ and then concentrated under reduced pressure. The product was finally purified by column chromatography (silica, pentane/dichloromethane) in order to provide 4.5 g of bis(8-azidooctyl) 2-methylpentanedioate as a colourless oil (4.5 g, 62%).

1H NMR (CDCl3) δppm: 4.061 (t, J=6.8 Hz, 2H); 4.054 (t, J=6.8 Hz, 2H); 3.25 (t, J=6.8 Hz, 4H); 2.47 (tq, J=7.2 and 1 Hz, 1H); 2.32 (m, 2H); 1.97 (m, 1H); 1.76 (m, 1H); 1.59 (m, 8H); 1.33 (m, 16H); 1.17 (d, J=7.2 Hz, 3H). 13C NMR (CDCl3) δppm: 176.03; 173.16; 64.52; 64.46; 51.44; 38.86; 31.95; 29.08; 29.02; 28.81; 28.59; 26.63; 25.79; 17.08. IR max/cm−1: 2931; 2857; 2091; 1730; 1462; 1456; 1252; 1160.

### Preparation of a First Solution S Containing the Semiconductors N and P

20 mg of P3HT and 20 mg of PCBM were dissolved in 1 mL of ODCB (ortho dichlorobenzene), by bringing the mixture to 60° C. under agitation (hot plate), in a manner so as to obtain a stock solution S.

The solution S thus obtained was allowed to cool down to ambient temperature (20° C.).

### Preparation of Second Solution S′ Containing the Cross Linking Agent

A solution S′ consisting of bis(8-azidooctyl) 2-methylpentanedioate in ODCB was prepared at a concentration of 20 mg/mL of bis(8-azidooctyl) 2-methylpentanedioate.

### Mixing of the Two Solutions

Once the first solution S had cooled to 20° C., 100 μL of the solution S′ also at a temperature of 20° C., was introduced therein, whereby a composition was obtained that hereinafter is referred to as “ink 3”.

Immediate Production of the Photovoltaic Coating from the Mixture

Once this mixture had been prepared, the ink 3 was deposited in the form of a thin film on a glass plate. The film deposition was carried out by spin coating at 2000 revolutions per minute, with 5 seconds of acceleration and 60 seconds at 2000 revolutions per minute.

The deposition was carried out by making use of a freshly prepared mixture. In this regard, it is to be noted that the film deposition should be carried out within a period of minutes following the mixing of the solutions S and S′.

Subsequently the annealing at 80° C. was then carried out in order to ensure the cross linking.

### Example 4

### Stability Tests

The coatings produced in the Examples 1 to 3 were subjected to a heat treatment process at 150° C. and the change in their structure evolving over the course of time was monitored by means of optical microscopy.

By way of a comparison, the same experiment was performed with a coating produced under the conditions provided for the Example 1 but without addition of the solution S′ to the solution S.

The tests demonstrate the substantial absence of formation of crystals with the thin films according to the invention whereas such crystals appear after a period of 20 minutes with the blank control sample.

### Example 5

### Change in the Photovoltaic Yield—Output Over Time

A photovoltaic cell was produced by using the coating produced according to the Example 1; and these cells were brought to 150° C., where the change in the photovoltaic yield over time was studied and the period of time t_{80%}at the end of which the yield drops by 80% was noted. The results are reported in the table here below:

| | t_{80% (in hours)} |
|---|---|
| Blank control sample | 4 hours |
| Example 1 | 70 hours |

### Example 6

### Production of a Cross Linked Photovoltaic Coating ([60]PCB-C3-N3 or [60]PCB-C6-N3)

This example describes the preparation of the [60]PCB-C3-N3 or [60]PCB-C6-N3 coatings, which have been obtained according to the identical protocols.

### Preparation of the [60]PCB-C3-N3 and [60]PCB-C6-N3 Compounds

[60]PCBA was obtained by means of hydrolysis of [60]PCBM in accordance with the procedure described by J C Hummelen, B W Knight, F LePeq and F. Wudl in J. Org. Chem., vol. 60, pp. 532-538 (1995). F. Wudl LePeq J. Org. Chem., Vol. 60, pp. 532-538 (1995)

From this [60]PCBA, the [60]PCB-C3-N3 and [60]PCB-C6-N3 were prepared separately, in accordance with the following esterification protocol:

To a solution (degassed by argon bubbling) of [60]PCBA (200 mg, 0.245 mmol) in CH₂Cl₂ (HPLC grade—stabilised with amylene) (30 mL), the following were added successively: hydroxybenzotriazole (HOBt) (33 mg, 0.223 mmol), N-(3-dimethylaminopropyl)-N′-carbodiimide (EDC) (120 μL, 0.669 mmol), 4-dimethylaminopyridine (27 mg, 0.223 mmol), and then a solution in 10 mL of CH₂Cl₂, of 1.11 mmol of 3-azidopropan-1-ol (for the synthesis of [60]PCB-C3-N3)) or 1.11 mmol of 6-azidohexan-1-ol (for the synthesis of [60]PCB-C6-N3).

The reaction mixture was stirred at ambient temperature under argon atmosphere for a period of 3 days. The solvent was then eliminated by means of concentration using a rotary evaporator and the residue was purified by chromatography on silica gel with CH₂Cl₂/Pentane 7/3 or 8/2 as the mixture of solvents. After concentration of the solvent (without heating the bath of the rotary evaporator), the compounds [[60]PCB-C3-N3 and [60]PCB-C6-N3 were obtained in the form of a black powder with a yield of 70% to 80%. These compounds were rapidly brought to dissolution at a concentration of 20 mg/mL in ODCB.

The 3-azidopropan-1-ol and 6-azidohexan-1-ol used were prepared by reaction of NaN₃ with the commercially available 3-bromopropan-1-ol and 6-bromohexan-1-ol, in accordance with the procedures described respectively in Journal of Materials Chemistry, vol. 22, pp. 1100-1106 (2012) and Journal of Medicinal Chemistry, vol. 54, pp. 7363-7374 (2011).

The compounds obtained have the following characteristics:

[60]PCB-C3-N3:

¹H NMR (CDCl₃, 300 MHz): δ=7.94 (d, J=6.0 Hz, 2H; o-H), δ=7.53 (m, 3H; m, p-H), δ=4.17 (t, J=6.3 Hz, 2H, COOCH₂), δ=3.36 (t, J=6.6 Hz, 2H, CH₂N₃), δ=2.91 (m, 2H; PhCCH2), δ=2.53 (t, J=7.2 Hz, 2H; CH₂COO), δ=2.18 (m, 2H; CH₂CH₂COO), δ=1.9 (m, 2H; CH₂CH₂N₃).

¹³C NMR (CDCl₃, 75 Mhz): 172.9, 148.7, 147.7, 145.8, 145.2, 145.0, 144.8, 144.6, 144.5, 144.4, 144.0, 143.7, 143.0, 142.99, 142.91, 142.2, 142.16, 142.12, 140.9, 140.7, 138.0, 137.5, 136.7, 132.1, 128.4, 128.3, 79.8, 61.5, 51.8, 48.2, 33.9, 33.6, 28.1, 22.3. MS (MALDI-TOF, pos. mode, dithranol): m/z: 979.13, calcd for: C₇₇H₁₇N₃O₂. found: 980.2 [M]′.

[60]PCB-C6-N3:

¹H NMR (CDCl₃, 300 MHz): δ=7.94 (d, J=6.9 Hz, 2H; o-H), δ=7.52 (m, 3H; m, p-H), δ=4.07 (t, J=6.6 Hz, 2H, COOCH₂), δ=3.26 (t, J=6.6 Hz, 2H, CH₂Br), δ=2.91 (m, 2H; PhCCH2), δ=2.53 (t, J=7.5 Hz, 2H; CH₂COO), δ=2.23-2.15 (m, 2H; CH₂CH₂COO), δ=1.63 (m, 4H; CH₂CH₂N₃ and COOCH₂CH₂), δ=1.4-1.33 (m, 4H; COOCH₂CH₂CH₂CH₂).

¹³C NMR (CDCl₃, 75 MHz): 173.1, 148.8, 148.0, 145.9, 145.8, 145.3, 145.2, 145.2, 145.1, 145.0, 145.0, 144.8, 144.7, 144.7, 144.6, 144.5, 144.4, 144.0, 143.7, 143.1, 143.02, 142.97, 142.92, 142.90, 142.2, 142.2, 142.1, 142.0, 141.0, 140.7, 138.0, 137.5, 136.7, 132.1, 128.4, 128.2, 79.9, 64.5, 51.8, 51.3, 34.1, 33.6, 28.7, 28.5, 28.4, 26.4, 25.5, 22.4 MS (MALDI-TOF, pos. mode, dithranol): m/z: 1021.18, calcd for: C₇₇H₂₃N₃O₂. found: 1022.19 [M]⁺.

### Preparation of a First Solution S1 Containing the Semiconductor N

40 mg of P3HT was dissolved in 1 mL of ODCB (ortho-dichlorobenzene), by bringing the mixture to δ0° C. under agitation (hot plate), in a manner so as to obtain a first stock solution S1.

The resulting solution S1 thus obtained was allowed to cool down to ambient temperature (20° C.).

### Preparation of a Second Solution S2 Containing the Semiconductor P

40 mg of PCBM was dissolved in 1 mL of ODCB (ortho-dichlorobenzene), by bringing the mixture to δ0° C. under agitation (hot plate), in a manner so as to obtain a second stock solution S2.

The resulting solution S2 thus obtained was allowed to cool down to ambient temperature (20° C.).

### Preparation of Third Solution S′ Containing the Cross Linking Agent ([60]PCB-C3-N3 or ([60]PCB-C6-N3)

A solution S′ consisting of [60]PCB-C3-N3 (or indeed respectively of [60]PCB-C6-N3) in ODCB was prepared at a concentration of 40 mg/mL of [60]PCB-C3-N3 (or indeed respectively of [60]PCB-C6-N3).

The resulting solution S′ thus obtained was allowed to cool down to ambient temperature (20° C.).

### Mixing of the Three Solutions

Once the three solutions had cooled to 20° C., 1 mL of solution S1 was mixed with 850 μL of solution S2, and to this mixture was added 150 microlitre of solution S′, due to which a composition was obtained that hereinafter is referred to as “ink δ”.

Immediate Production of the Photovoltaic Coating from the Mixture

Once this mixture had been prepared, the ink 6 was deposited in the form of a thin film on a glass plate. The film deposition was carried out by spin coating at 1000 revolutions per minute, with 1 second of acceleration and 60 seconds at 1000 revolutions per minute.

The deposition was carried out by making use of a freshly prepared mixture. In this regard, it is to be noted that the film deposition should be carried out within a period of minutes following the mixing of the solutions.

Subsequently the annealing at 80° C. was then carried out in order to ensure the cross linking.

### Example 7

### Properties of the Film Layers Obtained

The coatings produced in the Example 6 were subjected to a heat treatment process at 150° C. and the change in their structure evolving over the course of time was monitored by means of optical microscopy.

By way of a comparison, the same experiment was performed with a coating produced under the conditions provided for the Example 6 but without addition of ([60]PCB-C3-N3) or ([60]PCB-C6-N3).

The tests demonstrate the substantial absence of formation of crystals with the thin films according to the invention whereas such crystals appeared to have covered the entire surface of the film layer after a period of 24 hours with the blank control sample.

A photovoltaic cell was produced using the coating produced according to the Example 6; and these cells were brought to 150° C., where the change in the photovoltaic yield over time was studied.

By way of a comparison, the same experiment was performed with a photovoltaic cell by using the coating produced according to the Example 6 but without the addition of the cross linking agent and the change in the PCE (Power Conversion Efficiency) evolving over the course of time was noted. The results obtained have been reported in the table here below:

| | PCE after 24 hrs of |
|---|---|
| | degradation |
| Blank control sample | 1.2 |
| Example 1 | 2.6 |

These tests demonstrate the thermal stability of the PCE cell with a thin layer produced according to the Example 6 based on the invention whereas the PCE of the Blank control cell drops significantly after a period of 24 hours.

1. A method for preparing a photovoltaic thin film having a heterojunction by depositing onto a substrate a composition, including an organic electron-donor semiconductor C_{P} and an organic electron-acceptor semiconductor C_{N}, and then carrying out phase segregation, including the following steps:
the preparation, in one or more steps, of a mixture M comprising the semiconductors C_{P} and C_{N} and the cross linking agents bearing azide groups in a suitable solvent that is appropriate for the phase segregation, under conditions providing for the temperature to be sufficiently low so as to inhibit the precipitation by cross linking of one and/or the other of the two organic semiconductors by means of reaction of the cross linking agents; and then
the depositing, on all or part of the surface of a substrate, of the mixture M thus produced and subsequently, carrying out the phase segregation by raising the temperature during or after this phase segregation and/or subjecting the reaction medium to a UV radiation having a suitable wavelength in a manner so as to be placed under conditions in which the cross linking additive reacts in order to form covalent bonds with at least a portion of the organic semiconductors, so that a cross linking within the photovoltaic thin film produced is obtained.

2. The method according to claim 1, including the following steps:
(E1) the preparation of a first mixture M1 comprising the organic semiconductors C_{N} and C_{P} in a solvent medium;
then
(E2) the addition to this mixture M1 of a cross linking additive bearing at least two azide functions and possibly a solvent, under conditions providing for the temperature to be sufficiently low so as to inhibit the precipitation by cross linking of one and/or the other of the two organic semiconductors with the cross linking additive during the step (E2), in a manner so as to form a mixture M comprising the semiconductors C_{P} and C_{N} and the additive in a suitable solvent that is appropriate for the phase segregation;
and then
(E3) the depositing, on all or part of the surface of a substrate, of the mixture M thus produced and subsequently, carrying out the phase segregation, by raising the temperature during or after this phase segregation and/or subjecting the reaction medium to a UV radiation having a suitable wavelength in a manner so as to be placed under conditions in which the cross linking additive reacts in order to form covalent bonds with at least a portion of the organic semiconductors, so that a cross linking within the photovoltaic thin film produced is obtained.

3. The method according to claim 1, including the following steps
(E1) the preparation of a first mixture M1 comprising only a portion of the organic semiconductors C_{N} and C_{P} in a solvent medium; then
(E2) the addition to this mixture M1 of the remainder of the organic semiconductors, previously modified by the grafting of azide functions and possibly a solvent, under conditions providing for the temperature to be sufficiently low so as to inhibit the precipitation by cross linking of one and/or the other of the two organic semiconductors with the cross linking additive during the step (E2), in a manner so as to form a mixture M comprising the semiconductors C_{P} and C_{N} and the additive in a suitable solvent that is appropriate for the phase segregation; and then
(E3) the depositing, on all or part of the surface of a substrate, of the mixture M thus produced and subsequently, carrying out the phase segregation; and, during or after this phase segregation, and typically only after the phase segregation, raising the temperature and/or subjecting the reaction medium to a UV radiation having a suitable wavelength in a manner so as to be placed under conditions in which the cross linking additive reacts in order to form covalent bonds with at least a portion of the organic semiconductors, so that a cross linking within the photovoltaic thin film produced is obtained.

4. The method according to claim 3, wherein the organic semiconductors, previously modified by the grafting of azide functions that are used in the step (E2) are organic semiconductors C_{N} functionalised by at least one group bearing at least one azide function.

5. The method according to claim 1, wherein the organic semiconductor compound C_{N} is selected from among the following compounds:
fullerenes and fullerene derivatives;
types of polymers;
PCNEPV (Poly[oxa-1,4-phenylene-(1-cyano-1,2-vinylene)-(2-methoxy-5-(3,7-dimethyloctyloxy)-1,4-phenylene)-1,2-(2-cyanovinylene)-1,4-phenylene]); and
poly(styrene sulfonate) (PSS).

6. The method according to claim 1, wherein the organic semiconductor compound C_{P} is selected from among the following compounds:
polythiophene derivatives;
tetracene;
anthracene;
polythiophene;
derivatives of PPV (Poly phenylene vinylene); and
low band gap polymers, like PCDTBT.

7. The method according to claim 1, wherein the organic semiconductor compound C_{N} is a fullerene derivative, and the organic semiconductor compound C_{P} is a polythiophene derivative.

8. The method according to claim 1, wherein the organic semiconductor compound C_{N} is a fullerene derivative and the molar ratio of the cross linking agent/semiconductor C_{N} is less than 2.

9. The method according to claim 1, wherein:
(E1) the first mixture M1 is prepared and comprises, in the solvent medium S1, the organic semiconductor C_{P} and the second organic semiconductor C_{N};
(E2) to this mixture M1, the cross linking additive is added in the form of a mixture M2 comprising of the additive in a second solvent medium S2, due to which a mixture M is obtained that comprises of a solvent S including the solvent S1 and the optional solvent S2,
wherein the solvent S of the mixture M is constituted of a mixture of:
a first fraction F1 consisting of a solvent or mixture of solvents having a boiling point lower than that of the compounds C_{P} and C_{N} and which is capable of solvating the two compounds C_{P} or C_{N};
a second fraction F2, miscible with the first fraction, consisting of a solvent or mixture of solvents which has a boiling point that is higher than that of the fraction F1 and lower than that of the compounds C_{P} and C_{N} and which is capable of selectively solvating one of the compounds C_{P} or C_{N} but not the other (that is to say, unable to solvate respectively C_{N} or C_{P});
this addition being carried out under conditions providing for the temperature to be sufficiently low so as to inhibit the cross linking of one and/or the other of the two organic semiconductor by the cross linking agent during the step (E2);
(E3) the mixture M thus produced is deposited on all or part of the surface of a substrate, and the solvent S present in the deposit thus produced is eliminated by means of evaporation, and simultaneously or subsequently, the medium is brought to a temperature that is sufficient in order to ensure that the cross linking is performed.

10. The method according to claim 1, wherein the step (E2) is carried out at a temperature lower than 50° C.

11. The method according to claim 1 wherein the cross linking agent is 4,4′-bis(azidomethyl)-1,1′-biphenyl (BPN).

12. The method according to claim 1 wherein the process is carried out under the following conditions:
(E1) the first mixture M1 is prepared and comprises, in a solvent S1, the organic semiconductor C_{P} and the second organic semiconductor C_{N};
(E2) to this mixture M1, is added a composition including at least one cross linking additive of the aforementioned type, possibly dissolved in the same solvent S1 as that of the mixture M1;
wherein:
the solvent S1 is a solvent medium having a boiling point lower than that of the compounds C_{P} and C_{N} and which is capable of solvating the two compounds C_{P} or C_{N}; and
the cross linking additive is a compound miscible with the solvent S1, which has a boiling point that is higher than that of Si and lower than that of the compounds C_{P} and C_{N} and which is capable of selectively solvating one of the compounds C_{P} or C_{N} but not the other (that is to say, unable to solvate respectively C_{N} or C_{P});
this addition being carried out under conditions providing for the temperature to be sufficiently low so as to inhibit the cross linking of one and/or the other of the two organic semiconductors by the cross linking agent during the step (E2),
(E3) the mixture M thus produced is deposited on all or part of the surface of a substrate, and the solvent S1 is eliminated by means of evaporation, due to which a texturing of the film is obtained, and subsequently, the textured coating thus obtained is brought to a temperature that is sufficient in order to ensure that the cross linking is performed.

13. A photovoltaic thin film that may be obtainable in accordance with the method as claimed in claim 1.

14. A compound having the formula N₃—Ra—O—C═O—Rb—C═O—O—Ra—N₃
where
—Ra— is a saturated or unsaturated, linear or branched hydrocarbon chain, and
—Rb— is a saturated or unsaturated, linear or branched hydrocarbon chain.

15. The compounds [60]PCB-C3-N3 and [60]PCB-C6-N3, as obtained by hydrolysis of PCBM into PCBA, and then followed by esterification of the PCBA obtained respectively with HO—(CH₂)₃—N₃ and with HO—(CH₂)₆—N₃.

16. The method according to claim 4, wherein the organic semiconductors, previously modified by the grafting of azide functions that are used in the step (E2), are the compounds [60]PCB-C3-N3 or [60]PCB-C6-N3 obtained by hydrolysis of PCBM into PCBA, and then followed by esterification of the PCBA obtained respectively with HO—(CH₂)₃—N₃ and with HO—(CH₂)₆—N₃.
